(19) United States
(12) Patent Application Publication
(10) Pub. No.: US 2025/0210590 A1
(43) Pub. Date: Jun. 26, 2025

(54) ASIC INTEGRATED MEMS DEVICE WITH EXPOSED BOND PADS FROM BOTTOM ATTACHED ASIC AND MAKING THE SAME

(71) Applicant: SD OPTICS, INC., SEOUL (KR)

(72) Inventors: KYUNG PYO HONG, SEOUL (KR); JIN YOUNG SOHN, SEOUL (KR); GYOUNG IL CHO, SEOUL (KR); CHEONG SOO SEO, SEOUL (KR)

(21) Appl. No.: 18/394,866

(22) Filed: Dec. 22, 2023

(51) Int. Cl. H01L 25/065; H01L 21/66; H01L 21/8234; H01L 23/00

(52) U.S. Cl. CPC H01L 25/0657; H01L 22/32; H01L 24/03; H01L 24/08; H01L 24/48; H01L 24/94; H10D 84/0126; H10D 84/038; H01L 24/32; H01L 24/73; H01L 2224/03002; H01L 2224/08148; H01L 2224/32225; H01L 2224/48229; H01L 2224/73265; H01L 2224/94; H01L 2225/0651; H01L 2225/06541; H01L 2225/06562; H01L 2924/1433; H01L 2924/1461

(57) ABSTRACT

The present invention introduces the ASIC integrated MEMS device with exposed bond-pads from bottom attached ASIC and method for making the same. The ASIC integrated MEMS device with exposed bond-pads from bottom attached ASIC can be especially used for micromirror array MEMS devices. With the present invention and technology, individually controlling of thousands of micromirrors becomes possible and bring easier fabrication method. With the present invention and technology, individually controllable micromirror array can implement easier control method and more compact packing becomes feasible. With help of the present invention scheme, more complicated light modulating device scheme can be implemented with micromirror array or MEMS device with a large number of controlling channels. Scheme, apparatus, and method are disclosed in the present invention.

### FIELD OF THE INVENTION

The present invention relates to general MEMS (Micro-Electro Mechanical Systems) device with integrated driving ASIC (Application Specific Integrated Circuits) with wafer bonding method and fabrication and packaging method for the device.

### BACKGROUND OF THE INVENTION

MEMS is micro-electro mechanical systems, and devices with MEMS technology incorporating both electronic and moving parts and are extremely small, ranging in size from micrometers to hundreds of micrometers. In addition, MEMS devices utilize electrostatic forces, surface tension, and mechanical forces. Electrostatic forces use capacitive forces between charges to attract each other, so it has the advantage of very low power consumption and fast operation speed. Also frequently, MEMS devices are built with semiconductor processing techniques. This enables mass production of extremely small products at a low cost. MEMS devices are utilized as actuators and sensors in various fields, including automotive airbag sensors, smartphone accelerometer sensors, and biochips for decoding genetic information. In general, the connection with the CMOS circuit for driving MEMS is established using wire bonding, as shown in FIG. 1. However, with the increasing research and development of MEMS devices and the growing applications, the operation of MEMS devices has become more complex, requiring numerous control channels to accommodate various modes of operation and degrees of freedom, as shown in FIG. 2.

In particular, for MEMS devices, such as digital micromirror arrays composed of hundreds to thousands of micromirrors inside a device, the number of electrodes required for driving each micromirror unit cell is 2 to 3. Therefore, to accommodate the entire array with independent motions, the number of electrodes becomes extremely extensive. Moreover, to control each micromirror independently, it requires more control channels than the number of mirrors, sometimes three times or four times of the number of the micromirrors. However, there are physical limitations to make wire-connection to the individual electrodes. One of the solution was utilizing CMOS (Complementary Metal-Oxide Semiconductor) circuitry on semiconductor wafers instead of wire bonding individual channel. Moreover, even if wire bonding is feasible, constructing a controller to control with many channels remains challenging and requires significant investments in terms of space and cost.

To overcome these difficulties, Texas Instruments and Fraunhofer have adopted a method for producing a micromirror array device by directly stacking MEMS structures on top of a CMOS wafer, as shown in FIG. 3A in U.S. Pat. No. 9,950,924 B2 issued Apr. 24, 2018 to Sridharamurthy, U.S. Pat. No. 8,541,850 B2 issued Sep. 24, 2013 to Gupta, and U.S. Pat. No. 9,546,090 B1 issued Jan. 17, 2017 to Xia. Since MEMS structures are deposited directly on the CMOS circuit wafer, there is no need for wire bonding, enabling a rapid electrical transmission speed could be achieved.

DMD (Digital Micromirror Device) developed by Texas Instruments is one of micromirror devices consisting of millions of mirrors capable of rotating between 12 to 17 degrees from its non-operating position, as shown in FIG. 3B in U.S. Pat. No. 5,583,688 issued Dec. 10, 1996 in Honrbeck. DMD mirrors change the amount of optical tilt, which controls the light of the corresponding pixel and using PWM (Pulse Width Modulation) technique, it can control the brightness of the pixels. DLP (Digital Light Processing) projectors with DMDs are used in a variety of applications, including large theaters, automotive heads-up displays, and augmented reality in U.S. Pat. No. 10,527,726 B2 issued Jan. 7, 2020 to Bartlett. However, the motion of DMD is limited to binary states of on and off, making it incapable of controlling the amount of rotation. It can only be digitally controlled with an On/Off mechanism. Therefore, it cannot be used for applications where the angular amount of individual micromirrors should be controlled, such as adaptive optics for wavefront correction, due to limitations of technology and as more complicated spatial light modulating devices.

Fraunhofer's micromirror systems implement 1-axis tilting micromirrors that rotate around a central axis, 2-axis tilting micromirrors capable of tilting in any direction around a central axis, and piston motion micromirrors that transforms in the direction perpendicular to the micromirror surface. These micromirrors find application in adaptive optics and the field of wavefront correction, where individual control of the angles of millions of micromirrors is necessary. Fraunhofer has designed multiple drivers and controllers to secure an adequate number of I/O channels for individual angle control. However, the drawback arises from the need to assemble numerous drivers and controllers, leading to constraints in space and cost.

Direct deposition of MEMS structures on top of CMOS wafer, as applied by Texas Instruments and Fraunhofer, can eliminate the wire bonding process, resulting in faster electrical transfer, lower costs, and greater convenience. The main difficulty of the MEMS-CMOS integration process in wafer level with these advantages was temperature. CMOS devices are typically at relatively low temperature between 15° and 400° C. for the semiconductor processes. If the CMOS device undergoes above 400° C., the device performance would be seriously degraded, described in U.S. Pat. No. 9,343,668 B2 issued May 17, 2016 to MaxWell. Therefore, in order to deposit MEMS structures at these process temperatures, it is necessary to deposit metallic (Cu, Ni, Ti, etc.) MEMS only with relatively low process temperatures (under 400° C.) in U.S. Pat. No. 9,630,834 B2 issued Apr. 24, 2017 to Tayebi.

Generally, materials such as metals, ceramics, and polysilicon are widely used in the deposition of MEMS structures. Polysilicon offers superior electrical and mechanical characteristics, and its high melting point compared to metals provides the advantage of stable operation. However, the processing temperature for polysilicon typically requires a minimum of around 580° C. and can go up to approximately 1000° C. in U.S. Pat. No. 9,006,016 B2 issued Apr. 14, 2015 to Celik-Butler, U.S. Pat. No. 10,071,905 B2 issued Sep. 11, 2018 to Chu. Due to high processing temperature, the stability of CMOS circuits cannot be insured. Thus, strong demand for a MEMS-CMOS integrated method that allows the use of polysilicon is increasing, which exhibits excellent characteristics as a MEMS material also.

In the present invention, CMOS ASIC wafers capable of controlling multiple channels and polysilicon-based MEMS wafers are separately fabricated and then bonded together using wafer-level wafer bonding technique. Before wafer bonding while fabricating MEMS structures, fine holes (via) penetrating the MEMS wafer vertically are formed. The TSV (through silicon via) method is applied here, wherein the holes are filled with a conductive material to establish a direct electrical connection pathway within the wafer, securing electrical connectivity and surroundings are insulated through the insulating layers around the TSVs in U.S. Pat. No. 10,833,052 B2 issued Nov. 10, 2020 to Shih, U.S. Pat. No. 9,997,497 B2 issued Jun. 12, 2018 to Yu. The TSV method provides a direct connection pathway through the MEMS wafer, eliminating the need for wire bonding of multiple electrodes to the CMOS ASIC wafers. This can eliminate the limitations of the number of I/O channels and problems like short circuits and contact defects. However, while TSV enables the connection between the electrodes of MEMS structures and CMOS ASIC, bond pads are still necessary to supply the control signal data and power required for the control of CMOS ASIC, thus MEMS structures through TSVs usually CMOS ASIC is wafer-bonded underneath the MEMS wafer.

In the present invention, MEMS and CMOS ASIC wafers are diced with a slight separation between MEMS and CMOS ASIC wafers to have access to the bond pads of CMOS ASIC wafer. So independent dicing of each wafer is required after wafer bonding. If dicing of each wafer is performed before wafer bonding, even a small alignment error during the bonding process can cause the device to fail and individual device bonding is required. Therefore, dicing should be performed separately after bonding. There are several methods for dicing wafers, including blade (diamond) dicing, which uses physical contact, laser dicing, which uses lasers, and plasma dicing, which uses an etching process. In the case of blade dicing, chipping occurs during the process of cutting the wafer surface, which can adversely affect the MEMS structure. In the case of laser dicing, the occurrence of chipping and cracks can be minimized, resulting in high-quality devices. However, when the wafer thickness exceeds 100 μm, productivity is low, and there are drawbacks such as needs for additional processes like cooling or cleaning.

Stealth dicing is a method that uses laser energy to cut the inside of the wafer first, and then applies external pressure to the tape on the outside to break the epidermis to separate the chips. When pressure is applied to the backing tape, the wafer is momentarily bent upward by the expanded tape, and the chips are separated individually. This method eliminates the generation of debris when directly dicing the surface with a laser. Moreover, the kerf width, which is the width of the cut line, can be narrowed as a laser spot size, allowing for the incorporation of numerous chips on the wafer. Also, there is an advantage in terms of reduced chipping and crack occurrence, which are critical factors determining overall dicing quality especially released MEMS devices. By applying stealth dicing technology, it is possible to perform split-dicing by individually dicing the bonded MEMS wafer and CMOS ASIC wafer after wafer bonding. This process enables the fabrication of systems that integrate CMOS ASICs and MEMS devices with exposed bond-pads from the CMOS ASIC device area.

To overcome the disadvantages of the previous technologies, the present invention introduces the ASIC integrated MEMS device with exposed bond-pads from bottom attached ASIC and method for making the same. The ASIC integrated MEMS device with exposed bond-pads from bottom attached ASIC can be especially used for micromirror array MEMS devices. With the present invention and technology, individually controlling of thousands of micromirrors becomes possible and bring easier fabrication method. With the present invention and technology, individually controllable micromirror array can implement easier control method and more compact packing becomes feasible. Example and its application of the individually controllable micromirror array is described in the U.S. patent application Ser. No. 18/384,721 filed Oct. 27, 2023, which is incorporated herein by references.

Micromirror Array Lens System (MMAL) is another example for application of the ASIC integrated MEMS device with exposed bond-pads from bottom attached ASIC. More applications and MEMS structures with examples and the general principle, structure and methods for making the micromirror array devices and Micromirror Array Lens are disclosed in U.S. Pat. No. 7,330,297 issued Feb. 12, 2008 to Noh, U.S. Pat. No. 7,365,899 issued Apr. 29, 2008 to Gim, U.S. Pat. No. 7,382,516 issued Jun. 3, 2008 to Seo, U.S. Pat. No. 7,400,437 issued Jul. 15, 2008 to Cho, U.S. Pat. No. 7,411,718 issued Aug. 12, 2008 to Cho, U.S. Pat. No. 7,474,454 issued Jan. 6, 2009 to Seo, U.S. Pat. No. 7,777,959 issued Aug. 17, 2010 to Sohn, U.S. Pat. No. 7,488,082 issued Feb. 10, 2009 to Kim, U.S. Pat. No. 7,535,618 issued May 19, 2009 to Kim, U.S. patent application Ser. No. 11/347,590 filed Feb. 4, 2006, U.S. patent application Ser. No. 11/426,565 filed Jun. 26, 2006, U.S. patent application Ser. No. 11/534,613 filed Sep. 22, 2006, U.S. patent application Ser. No. 11/534,620 filed Sep. 22, 2006, U.S. patent application Ser. No. 11/693,698 filed Mar. 29, 2007, and U.S. patent application Ser. No. 11/762,683 filed Jun. 13, 2007, all of which are incorporated herein by references.

### SUMMARY OF THE INVENTION

The present invention implements multiple electrical connectors on a MEMS wafer with a Digital Micromirror Array deposited using the TSV technique. The MEMS drivers and controllers that control the micromirrors in the devices are fabricated on a CMOS ASIC wafer with ASIC circuitry using CMOS technology. By wafer-level bonding technique, a separately fabricated MEMS wafer and a CMOS ASIC wafer are wafer-bonded. The present invention enhances spatial efficiency and contributes to faster electrical transmission speeds. Stealth dicing technology is used to dice MEMS wafers and CMOS ASIC wafers separately without chip separation and with split spacing for the CMOS ASIC bond pad area. The present invention implements and proposes a method for an ASIC integrated MEMS device with exposed wire bond-pads from bottom attached ASIC.

The TSV technique can fabricate micro-via holes that penetrate vertically through a wafer to provide a direct electrical pathway. When the holes are fabricated in a via first process on a wafer where MEMS structures are to be deposited, small diameter TSVs can be fabricated, allowing for a high degree of routing freedom. This is advantageous for systems with multiple micromirrors arranged and requiring multiple I/O channels.

The TSV process involves creating holes in the wafer, either using laser drilling or chemical etching, and then filling the holes by plating. Due to alignment and byproduct handling issues, chemical etching methods are preferred over laser drilling. A typical chemical etching method is DRIE (Deep Reactive Ion Etching), which utilizes plasma. The present invention also utilizes the DRIE method to fabricate TSVs.

Typically, the sidewalls (trench) of micro-holes penetrated by TSV are filled with an insulating material, while the core is filled with a metal such as copper to ensure electrical properties. In the present invention, the sidewalls of the micro-holes penetrated by TSV are insulated with insulation material, and silicon is used for the conducting core. Through the fabricated TSV connectors, internal connection pathways are established within the MEMS wafer. Therefore, it is possible to directly connect numerous I/O channels to the CMOS ASIC wafer without the need for external wire bonding procedure. This allows for fast electrical transmission, overcoming spatial efficiency challenges, and saving time and costs associated for such a packaging method.

There are cases where MEMS devices have been directly fabricated on CMOS circuits. This method involves depositing metallic MEMS structures directly onto a wafer where the CMOS circuit is already fabricated, without the need for wire bonding between MEMS structures and CMOS circuits. However, a drawback of this approach is the necessity to maintain a process temperature below 400° C. to ensure the stability of CMOS components and minimize the impact of the thermal expansion coefficient of metals. With a process temperature limited to 400° C., only metallic materials can be utilized, and it becomes impractical to manufacture MEMS devices using polysilicon as the base material. Therefore, in the present invention, to use polysilicon as the base material for MEMS devices, the fabrication processes for MEMS devices and CMOS ASIC are carried out separately before performing wafer bonding. And this independent wafer building process gives an advantage of using pre-existing CMOS ASIC technology and MEMS technology.

The present invention overcomes the limitation of the process temperature by fabricating MEMS wafers and CMOS ASIC wafers separately. On MEMS wafers, polysilicon was deposited using a semiconductor process with a process temperature of 900 to 1000° C., and on CMOS ASIC wafers, CMOS circuits were fabricated with a process temperature of 400° C. A number of electrical connectors were fabricated on the MEMS wafers to allow direct connection to CMOS circuits using TSVs, and electrical junctions were fabricated on the CMOS ASIC to allow connection to the TSV connectors on the MEMS wafers.

In the separately fabricated MEMS wafer and CMOS ASIC wafer, the MEMS wafer performs insulation and flattening on the backside, creating multiple electrode areas. CMOS-AISC wafers uses front-side insulation and planarization, and fabricate multiple electrode regions. Each separately fabricated wafer aligns the lower electrode areas of the MEMS wafer with the upper electrode areas of the CMOS ASIC wafer, performing wafer bonding. The present invention realizes performance improvement and miniaturization by wafer bonding the MEMS and the CMOS ASIC wafers instead of wire bonding. Removing wire bonding process improves productivity of the CMOS ASIC integrated MEMS devices and also securing the connection of multiple electrodes.

After wafer bonding, an externally exposed bond pads from CMOS ASIC are required to supply control signal data and power required to the CMOS ASIC. For separate dicing of wafer-bonded MEMS wafers and CMOS ASIC wafers, the present invention applies split-dicing through the stealth dicing technology. First, the integrated MEMS-CMOS device is flipped upside down and the CMOS ASIC wafer from the bottom of the CMOS ASIC wafer is stealth diced to scribe the inside of the wafer with high laser energy. Before dicing the MEMS wafer, the integrated MEMS-CMOS device is flipped back over and the MEMS structure is released through the etch process. The release of the MEMS device is carried out first and removes the limitations of dicing and release process especially wafer bonded structures. After the MEMS device is released, the MEMS wafer is stealth diced from the top of the MEMS-CMOS integrated device. Stealth dicing helps not to have debris from the dicing process.

Since stealth dicing cuts through the interior of the wafer, the surfaces remain glued together. Therefore, an external force must be applied to the wafer to break the epidermis and separate the chips. Since stealth dicing involves cutting the inside of the wafer, the surfaces remain attached to each other. Therefore, external force should be applied to the tape attached to the wafer to fracture the epitaxial layer and separate the chips. Ultimately, when pulling the completed stealth dicing wafer from both sides, the diced surface with the empty interior breaks, causing the chips to separate. Upon completion of the above process resulting in chip separation, bond pads from the CMOS ASIC wafer are exposed outward with split dicing.

Also as applications of the ASIC integrated MEMS device with exposed bond-pads from bottom attached ASIC, the general principle and methods for making the Micromirror Array Lens are disclosed in U.S. Pat. No. 6,970,284 issued Nov. 29, 2005 to Kim, U.S. Pat. No. 7,031,046 issued Apr. 18, 2006 to Kim, U.S. Pat. No. 6,934,072 issued Aug. 23, 2005 to Kim, U.S. Pat. No. 6,934,073 issued Aug. 23, 2005 to Kim, U.S. Pat. No. 7,161,729 issued Jan. 9, 2007 to Kim, U.S. Pat. No. 6,999,226 issued Feb. 14, 2006 to Kim, U.S. Pat. No. 7,095,548 issued Aug. 22, 2006 to Cho, U.S. Pat. No. 7,239,438 issued Jul. 3, 2007 to Cho, U.S. Pat. No. 7,267,447 issued Sep. 11, 2007 to Kim, U.S. Pat. No. 7,274,517 issued Sep. 25, 2007 to Cho, and U.S. Pat. No. 7,777,959 issued Aug. 17, 2010 to Sohn, U.S. Pat. No. 7,489,434 issued Feb. 10, 2009 to Cho, U.S. Pat. No. 7,619,807 issued Nov. 17, 2009 to Baek, all of which are incorporated herein by references.

The general principle, structure and methods for making the micromirror array devices and Micromirror Array Lens are disclosed in U.S. Pat. No. 7,382,516 issued Jun. 3, 2008 to Seo, U.S. Pat. No. 7,330,297 issued Feb. 12, 2008 to Noh, U.S. Pat. No. 7,898,144 issued Mar. 1, 2011 to Seo, U.S. Pat. No. 7,474,454 issued Jan. 6, 2009 to Seo, U.S. Pat. No. 7,777,959 issued Aug. 17, 2010 to Sohn, U.S. Pat. No. 7,365,899 issued Apr. 29, 2008 to Gim, U.S. Pat. No. 7,589,884 issued Sep. 15, 2009 to Sohn, U.S. Pat. No. 7,589,885 issued Sep. 15, 2009 to Sohn, U.S. Pat. No. 7,400,437 issued Jul. 15, 2008 to Cho, U.S. Pat. No. 7,488,082 issued Feb. 10, 2009 to Kim, and U.S. Pat. No. 7,535,618 issued May 19, 2009 to Kim, U.S. Pat. No. 7,605,964 issued Oct. 20, 2009 to Gim, U.S. Pat. No. 7,411,718 issued Aug. 12, 2008 to Cho, U.S. Pat. No. 9,505,606 issued Nov. 29, 2016 to Sohn, U.S. Pat. No. 8,622,557 issued Jan. 7, 2014 to Cho, U.S. Pat. Pub. No. 2009/0303569 A1 published Dec. 10, 2009 to Cho, all of which are incorporated herein by references.

In Summary, the ASIC integrated MEMS device with exposed bond-pads from bottom attached ASIC: (1) the ASIC integrated MEMS device with exposed bond-pads from bottom attached ASIC can have a large number of control channels with easier access. (2) the ASIC integrated MEMS device with exposed bond-pads from bottom attached ASIC can have an unlimited number of control channels for micromirror array MEMS systems. (3) the ASIC integrated MEMS device with exposed bond-pads from bottom attached ASIC can provide an easier electrical connection method to the MEMS device with a large number of individually control channels. (4) the ASIC integrated MEMS device with exposed bond-pads from bottom attached ASIC can provide much simpler and compact control method for the multi-channel MEMS devices. (5) the ASIC integrated MEMS device with exposed bond-pads from bottom attached ASIC provides an approach for mass production through wafer level packaging method rather than individual device level, which can be a breakthrough for the highly populated multi-channel MEMS devices.

Although the present invention is briefly summarized, the full understanding of the invention can be obtained by the following drawings, detailed descriptions, and appended claims.

### DESCRIPTION OF FIGURES

These and other features, aspects and advantages of the present invention will become better understood with reference to the accompanying drawings, wherein

FIG. 1 illustrates general configuration of channel connections of MEMS and MEMS control logic circuit ICs (prior art);

FIG. 2 illustrates general configuration of complex wire bonding connecting MEMS with multiple micromirrors, control circuits, and controllers (prior art);

FIG. 3A illustrates structure of Texas Instrument DMD device layer by layer (prior art);

FIG. 3B illustrates structure of Texas Instrument DMD device operation schematics (prior art);

FIG. 4 illustrates the process of TSV (Via first process), first process of making TSVs;

FIG. 5 illustrates the process of TSV revelation after MEMS structures are built and prior to release etching. TSVs are released for connecting electrodes from top of the MEMS wafer to bottom of the MEMS wafer for further connections through the substrate;

FIG. 6 illustrates the process of backside metallization for the wafer bonding. Backside metallization is built for the electrical connection to the CMOS ASIC wafer and matched individually with electrode area of the CMOS ASIC wafer;

FIG. 7 illustrates the CMOS ASIC wafer which is the start of the wafer bonding of the CMOS ASIC wafer preparation and also the completion of CMOS ASIC wafer separately;

FIG. 8 illustrates the deposition process of bond metal for the CMOS ASIC wafer, which matches with backside of the MEMS wafer TSV positions of FIG. 6;

FIG. 9 illustrates wafer bond process with MEMS and CMOS ASIC wafers. Both wafers are aligned together with the TSV positions;

FIG. 10 illustrates stealth dicing process of CMOS ASIC wafer from the backside of bonded wafers;

FIG. 11 illustrates the release process of the MEMS structures. MEMS structure undergoes release etch process while the bonded wafers are not fully diced and maintain its position;

FIG. 12 illustrates the dicing process of MEMS wafer from the MEMS side of the wafer;

FIG. 13 illustrates the die separation process, which is performed after stealth dicing (scribing by the laser pulses) with stretching the attached film on the backside of the CMOS ASIC;

FIG. 14 illustrates the attachment of die onto PCB (print circuit board) and wire bonding. Individual die is glued onto the PCB and wire bonded through exposed bond pads from the CMOS ASIC wafer for control circuit connection;

FIG. 15 illustrates the packaging of the CMOS ASIC integrated MEMS device. Optical cover glass is used to protect the MEMS structures of the CMOS ASIC integrated MEMS device;

FIG. 16 illustrates an example of the fully packaged device of the CMOS ASIC integrated MEMS device, including electrical connections and optical cover to protect the MEMS structures;

### DETAILED DESCRIPTION OF THE ILLUSTRATED EMBODIMENTS

The present invention of the CMOS ASIC integrated MEMS device with exposed bond-pads from bottom attached CMOS ASIC give a new method for electrical connections with a large number of control signals and for implementing ASIC control circuitry with MEMS structures by the use of wafer bonding technology. The present invention of the CMOS ASIC integrated MEMS device with exposed bond-pads from bottom attached CMOS ASIC are described in detail for how to build and configure.

FIG. 1 (prior art) shows the typical system configuration where MEMS and control logic circuit ICs (prior art). The MEMS device (structures) 104 are fabricated on a MEMS wafer substrate 103 through MEMS and semiconductor processes. To establish a connection with the control logic circuit 101, the MEMS wafer substrate 103 is attached onto packaging PCB 106 of the final package together with the control logic circuit 101. In order to control the MEMS device 104, connections between the control logic circuit 101 and the MEMS device 104 is necessary. The bonded wires 102 between the control logic circuit 101 and the MEMS device 104 supply control signals and power to MEMS device 104. Separate wire bonding 105 can be carried out to supply independent power or signal to the MEMS device 104. For control via a PC or a controller, external wire bonding 107 is performed to supply control signal data and power from external source and controller. Further connectors can be installed through the packaging PCB 106.

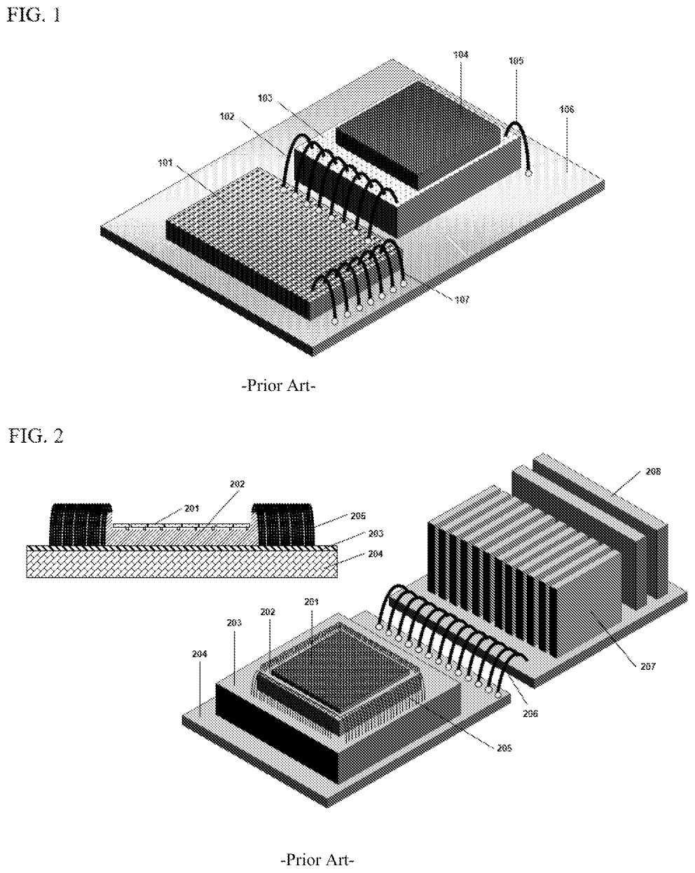

FIG. 2 (prior art) shows a more complex wire bonding structure including MEMS device 202 with MEMS structures (here micromirror array) 201, MEMS control device (CMOS logic circuit) 203, and multiple controller ICs 208. The MEMS structures 201, consisting of hundreds to thousands of micromirrors 201 to be controlled independently, is fabricated on a MEMS device (wafer) 202. The fabricated and diced MEMS device 202 is bonded onto packaging PCB 204, together with MEMS control device 203 (here mostly CMOS ASIC device). Wire bonding 205 is performed between the MEMS device 202 and MEMS control device 203 to provide control signal to the individual MEMS structures 201. Also for MEMS control device, there can be more control logic device such as driver ICs 207 and controller ICs 208. The integrated MEMS device 202 and MEMS control device 203 are connected with driver ICs 207 and controller ICs 208 through the external wire bonding or connector 206. Control signal data and power from an external source can be deliver through this external wire bonding or connector 206.

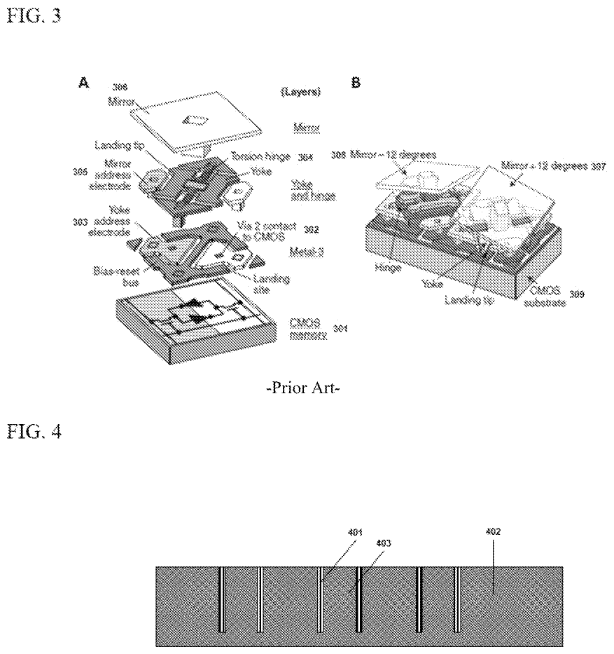

FIG. 3A (prior art) shows a layer schematic diagram of the DMD device from Texas Instrument. First CMOS memory 301 is built through standard semiconductor process. And then micromirror structures (yoke address electrodes 303, torsion hinge 304, mirror address electrodes 305, and mirrors 306) were built on top of the CMOS memory structures. The yoke address electrodes 303 and mirror address electrodes 305 are electrically connected to the CMOS memory through Via 302.

FIG. 3B (prior art) shows structure of Texas Instrument DMD device operation schematics. The individual micromirrors are operated with +/−12 degree rotation 307, 308 through the applied voltage from the CMOS substrate 309. Also the hinge structure 304 gives torsional restoration force for coming back to the original position.

One of the good examples of individually controlled micromirror device is Micromirror Array Lens. The general properties of the Micromirror Array Lens are disclosed in U.S. Pat. No. 7,173,653 issued Feb. 6, 2007 to Gim, U.S. Pat. No. 7,215,882 issued May 8, 2007 to Cho, U.S. Pat. No. 7,354,167 issued Apr. 8, 2008 to Cho, U.S. Pat. No. 9,565,340 issued Feb. 7, 2017 to Seo, U.S. Pat. No. 7,236,289 issued Jun. 26, 2007 to Baek, U.S. Pat. No. 9,736,346 issued Aug. 15, 2017 to Baek, all of which are incorporated herein by references.

The general principle, methods for making the micromirror array devices and Micromirror Array Lens, and their applications are disclosed in U.S. Pat. No. 7,057,826 issued Jun. 6, 2006 to Cho, U.S. Pat. No. 7,339,746 issued Mar. 4, 2008 to Kim, U.S. Pat. No. 7,077,523 issued Jul. 18, 2006 to Seo, U.S. Pat. No. 7,068,416 issued Jun. 27, 2006 to Gim, U.S. Pat. No. 7,333,260 issued Feb. 19, 2008 to Cho, U.S. Pat. No. 7,315,503 issued Jan. 1, 2008 to Cho, U.S. Pat. No. 7,768,571 issued Aug. 3, 2010 to Kim, U.S. Pat. No. 7,261,417 issued Aug. 28, 2007 to Cho, U.S. Pat. Pub. No. 2006/0203117 A1 published Sep. 14, 2006 to Seo, U.S. Pat. Pub. No. 2007/0041077 A1 published Feb. 22, 2007 to Seo, U.S. Pat. Pub. No. 2007/0040924 A1 published Feb. 22, 2007 to Cho, U.S. Pat. No. 7,742,232 issued Jun. 22, 2010 to Cho, U.S. Pat. No. 8,049,776 issued Nov. 1, 2011 to Cho, U.S. Pat. No. 7,350,922 issued Apr. 1, 2008 to Seo, U.S. Pat. No. 7,605,988 issued Oct. 20, 2009 to Sohn, U.S. Pat. No. 7,589,916 issued Sep. 15, 2009 to Kim, U.S. Pat. Pub. No. 2009/0185067 A1 published Jul. 23, 2009 to Cho, U.S. Pat. No. 7,605,989 issued Oct. 20, 2009 to Sohn, U.S. Pat. No. 8,345,146 issued Jan. 1, 2013 to Cho, U.S. Pat. No. 8,687,276 issued Apr. 1, 2014 to Cho, U.S. Pat. Pub. No. 2018/064562 A1 published Jun. 14, 2018 to Byeon, U.S. Pat. Pub. No. 2019/0149795 A1 published May 16, 2019 to Sohn, U.S. Pat. Pub. No. 2019/0149804 A1 published May 16, 2019 to Sohn, U.S. Pat. Pub. No. 2020/0341260 A1 published Oct. 29, 2020 to Gaiduk, U.S. Pat. No. 11,378,793 issued Jul. 5, 2022 to Winterot, U.S. Pat. Pub. No. 2021/0132356 A1 published May 6, 2021 to Gaiduk, all of which are incorporated herein by references.

The general principle, structure and methods for making the discrete motion control of MEMS device are disclosed in U.S. Pat. No. 7,330,297 issued Feb. 12, 2008 to Noh, U.S. Pat. No. 7,365,899 issued Apr. 29, 2008 to Gim, U.S. Pat. No. 7,382,516 issued Jun. 3, 2008 to Seo, U.S. Pat. No. 7,400,437 issued Jul. 15, 2008 to Cho, U.S. Pat. No. 7,411,718 issued Aug. 12, 2008 to Cho, U.S. Pat. No. 7,474,454 issued Jan. 6, 2009 to Seo, U.S. Pat. No. 7,488,082 issued Feb. 10, 2009 to Kim, U.S. Pat. No. 7,535,618 issued May 19, 2009 to Kim, U.S. Pat. No. 7,898,144 issued Mar. 1, 2011 to Seo, U.S. Pat. No. 7,777,959 issued Aug. 17, 2010 to Sohn, U.S. Pat. No. 7,589,884 issued Sep. 15, 2009 to Sohn, 2006, U.S. Pat. No. 7,589,885 issued Sep. 15, 2009 to Sohn, U.S. Pat. No. 7,605,964 issued Oct. 20, 2009 to Gim, and U.S. Pat. No. 9,505,606 issued Nov. 29, 2016 to Sohn, all of which are incorporated herein by references.

FIG. 4 shows an example of the manufacturing process for creating multiple electrical connectors that penetrate through a MEMS substrate using TSV technology. The micromirror array device requires thousands to tens of thousands of electrodes to control each micromirror independently. In addition to the physical limitations of wire bonding them externally, it also slows down the rate of electrical transfer. Direct connection through TSVs is one of good approaches to the MEMS and underlying CMOS control ASIC. For the present invention, via first process is used. To make TSVs, circular band type holes 401 are formed with DRIE process through the substrate wafer 402. Then the circular band type holes 401 are filled with insulation such as silicon oxide, which makes electrical isolation between the substrate wafer 402 and the core of the TSV structure 403. To maintain the core of the TSV structure 403, the DRIE etching is not performed through the whole substrate wafer 402. Later after building the MEMS structures, using backside grinding technique, the TSV structures will be revealed.

FIG. 5 shows the MEMS device manufactured on a MEMS wafer substrate 505 with penetrated TSV structures 506 (core and insulation). The MEMS structure building process (especially surface micromachining) involves repeating steps deposition and etching to create MEMS structures on the MEMS substrate wafer 505. Initially, an oxide insulation layer 504 is deposited (or thermal oxidation process) to protect the surface of the silicon substrate wafer 505, followed by the deposition of a nitride layer 503, serving as a protective barrier against release etching process and insulation. The areas of electrodes 507 will be formed on top of these insulations are then etched with conducting materials. Subsequently, deposition and etching processes are employed to sequentially create the poly silicon layers 501 and oxide layers 502. The oxide layers 502 as sacrificial layers will be etched and removed in subsequent processes in the release etch process.

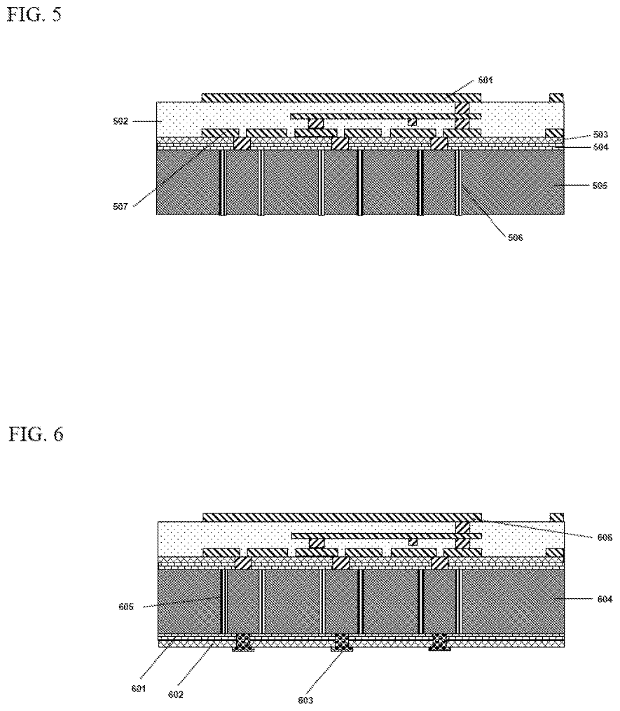

FIG. 6 shows the process of revealing the TSV structures 605 by grinding backside of the substrate wafer 604. To have good electrical connections and good wafer bonding, backside is ground and has planarization before wafer bonding metallization. Backside of the MEMS substrate wafer 604 after fabricating MEMS structures 606 is ground to reveal the TSV structures 605. For electrical connections individually, insulation should be formed between TSV structures 605. To achieve this, an oxide layer 601 is deposited to have electrical insulation of TSV structures 605 and the MEMS substrate wafer 604 to protect silicon not to have electrical connections. Followed by the insulation oxide layer 601, protecting nitride layer 602 is deposited as a protective barrier against release etching HF (hydrofluoric) acid. After deposition the insulating oxide layer 601 and the protecting nitride layer 602, the areas where electrodes will be formed are etched, and electrodes with metallization 603 are created using metallization process.

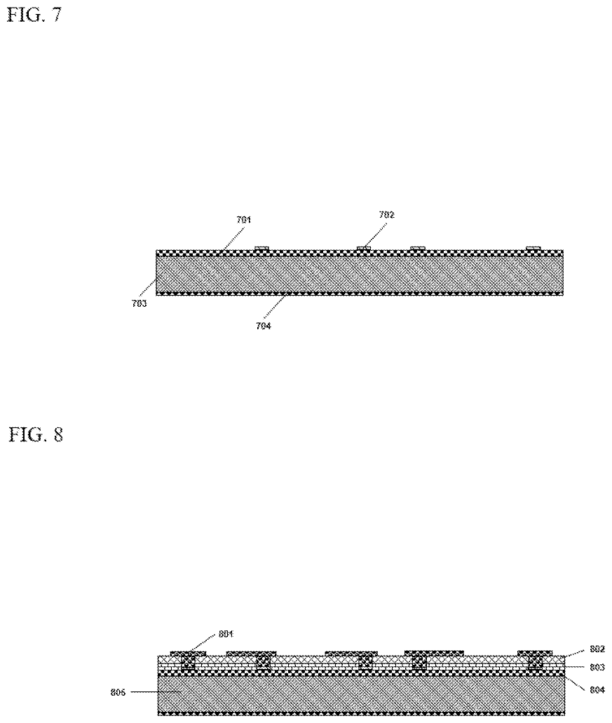

FIG. 7 shows preparation processes of the CMOS ASIC wafer. CMOS ASIC circuitry 701 is fabricated on top of CMOS ASIC substrate wafer 703 using CMOS fabrication semiconductor processes. In contrast to conventional devices where drivers and controllers are produced as separate modules, the present invention integrates drivers and controllers for MEMS device into the CMOS ASIC circuitry 701 on a CMOS ASIC wafer 703. By integrating drivers and controllers into the CMOS ASIC circuitry 701, there are advantages of rapid electrical transmission, miniaturization, and simple connections. An electrode area 702 for connecting with MEMS device is also created on the surface of the CMOS ASIC. To form control connection these electrode area 702 should be connected with TSV structures in the MEMS device wafer. To protect the surface, an insulating oxide layer 704 is deposited on the bottom of the silicon wafer.

FIG. 8 shows the process of creating metal bond pads for connecting with MEMS devices on top of CMOS ASIC wafer 805 while wafer bonding process. After making CMOS ASIC wafer with semiconductor processes, an oxide passivation layer 803 is deposited on top of the CMOS ASIC structures 804. Subsequently, a nitride protective layer 802 against release etching HF (hydrofluoric) acid, is deposited on top of the oxide passivation layer 803. After deposition of the nitride protective layer 802, the electrode area is etched, removing the nitride protective layer and oxide insulation layer. In the exposed electrode area, a metal electrode pads 801 made of Au material is fabricated for the connection with MEMS device electrodes with metallization.

FIG. 9 shows wafer-level bonding between the MEMS wafer and the CMOS ASIC wafer. To simplify the process, both the wafers of MEMS and CMOS ASIC are bonded in wafer level. The MEMS wafer 901, fabricated through MEMS and semiconductor processes, and the CMOS ASIC wafer 902, fabricated standard CMOS semiconductor processes, are aligned together matching each electrode on to on correspondence. Electrodes with metallization on the bottom of the MEMS wafer 901 and metal electrode pads produced on the top of the CMOS ASIC wafer 902 are bonded together and make electrical connections 903. From CMOS ASIC wafer electrodes, the electrical connection 903 through the TSV structures provide connection between MEMS wafer 901 electrodes and CMOS ASIC wafer 902 electrodes. The direct connection from the MEMS device to the CMOS ASIC device can remove wire bonding between the MEMS wafer 901 electrodes and CMOS ASIC wafer 902 electrodes. This direct connection is particularly advantageous for devices with hundreds to thousands of micromirrors and thus a large number of electrodes, allowing for rapid electrical transmission, miniaturization easy control.

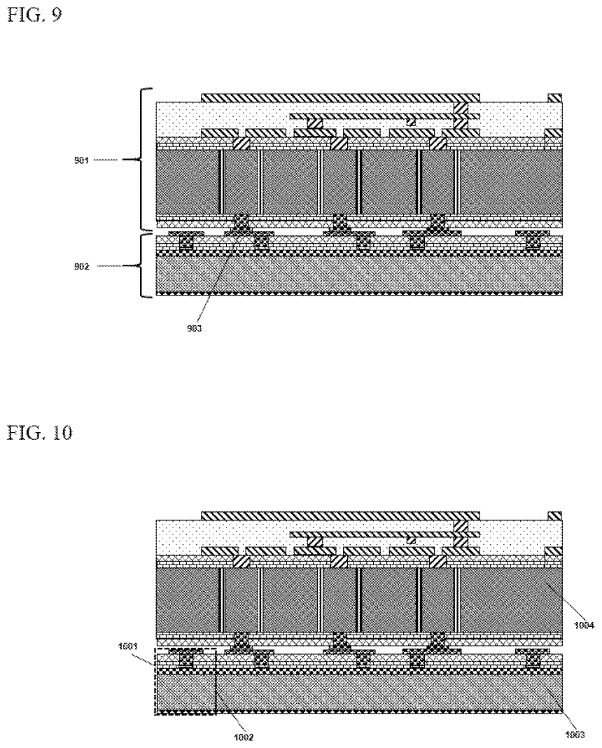

FIG. 10 shows stealth dicing process of the CMOS ASIC wafer 1003 after bonding with the MEMS wafer 1004. Since the dicing lines of the MEMS wafer and of the CMOS ASIC wafer are distinct and split, separate dicing processes are required for each wafer. For this specific example, stealth dicing is used and the wafers are maintained to be bonded together even after stealth diced (actually scribed inside the wafers). Stealth dicing involves focusing a laser beam with a wavelength that can penetrate the semiconductor wafer through an objective lens, concentrating it at a specific location inside the wafer. Utilizing high laser pulse energy, the internal portion (only focused portion) of the wafer is scribed with multi-photon absorption while the upper and lower surfaces adhered together. Subsequently, applying external force from the tape attached to the wafer for dicing causes the surface of the scribed wafer chips to break, leading to the separation of the chips by the dicing process. The area indicated by the dashed line on the CMOS ASIC wafer represents the separation region by stealth dicing 1001 that will be separated by the stealth diced cut line 1002 after stealth dicing.

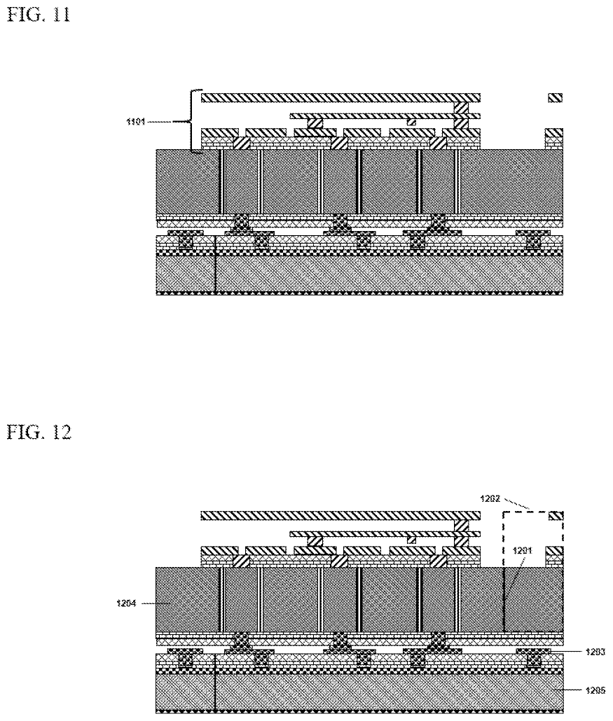

FIG. 11 shows the release process of the MEMS structures 1101. Since MEMS devices are extremely small, on the order of micrometers, careful handling is required during wafer processing. When producing MEMS devices through semiconductor processes and performing release directly through etching, handling the wafer for wafer bonding or stealth dicing may pose challenges. Therefore, after wafer bonding and CMOS ASIC wafer stealth dicing, the final release of the MEMS device is carried out. Followed by the release etching process, the MEMS structures 1101 indicated by the dashed line are revealed.

FIG. 12 shows stealth dicing process for the MEMS wafer 1204 after bonding with the CMOS ASIC wafer 1205. The dashed line represents the area of separation 1202 that will be separated after dicing the MEMS wafer, with the dicing line 1201. This area corresponds to the front part of the MEMS structure, aligned parallel to the wafer. Upon separation along the dashed line after dicing, the metal bond pads 1203 present on the CMOS ASIC wafer can be exposed.

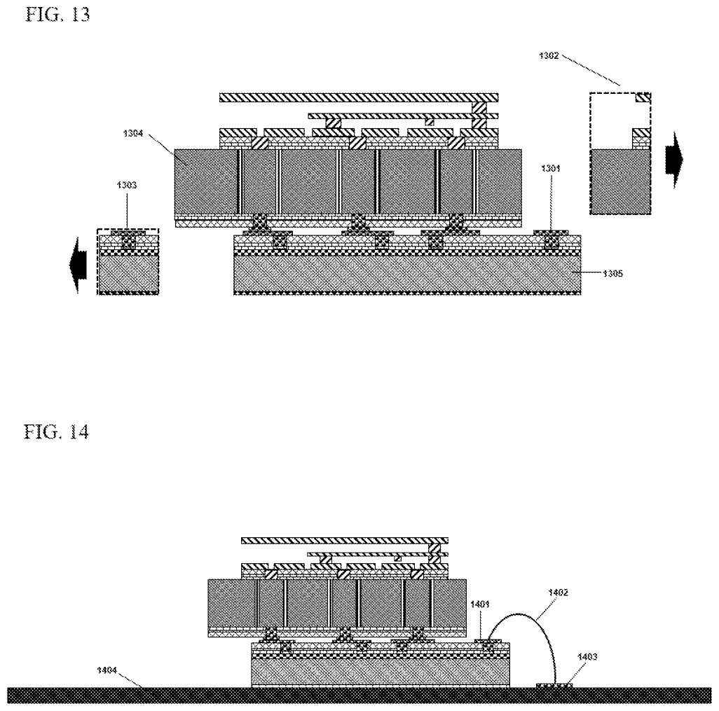

FIG. 13 shows the separation step of MEMS and CMOS ASIC wafers by applying external force to the tape (blue film) attached for stealth dicing to separate the individual devices. Since stealth dicing involves cutting only the internal part of the wafer with laser energy (actually internal scribing not dicing), the upper and lower surfaces remain attached. After completion of the laser processes on both the CMOS ASIC wafer 1305 and the MEMS wafer 1304, the tape attached to the wafer under the CMOS ASIC wafer 1305 is pulled for separating the devices from the bonded wafers. As the device separation 1302 for the MEMS wafer and chip separation 1303 for the CMOS ASIC wafer occur, the bond pads 1301 fabricated on top of the CMOS ASIC are exposed externally. These exposed bond pads 1301 supply the necessary control signal data and power for controlling the MEMS device.

FIG. 14 shows the appearance of the MEMS and CMOS ASIC integrated system after attaching the device onto a PCB. The exposed bond pads 1401 revealed through stealth dicing are connected to the bond pads 1403 on the packaging PCB 1404 using wire bonding 1402. This provides the control signal data and the power for MEMS actuation from external sources. This simple wire bonding can reduce lots of direct connected wire bonding through the CMOS ASIC device.

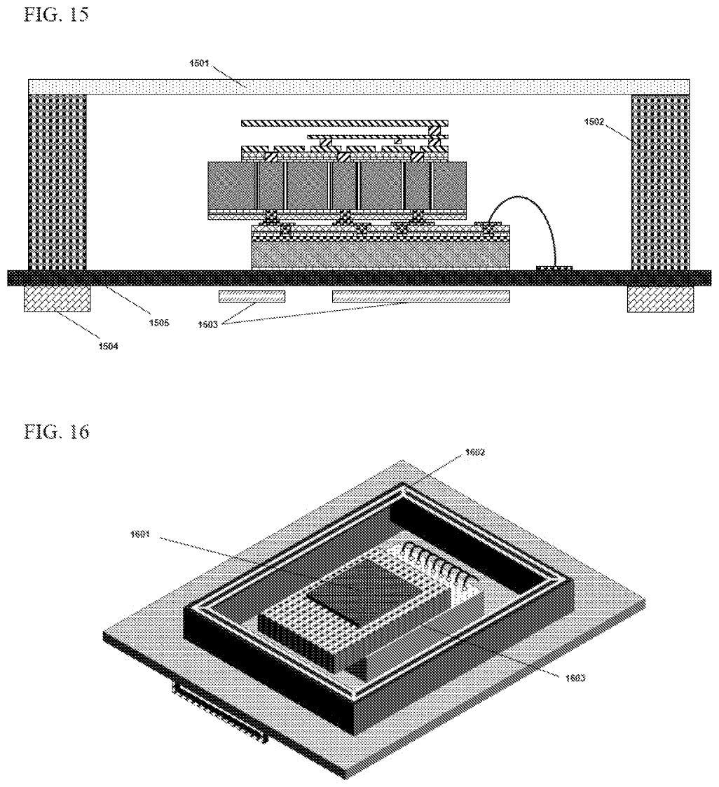

FIG. 15 shows the final packaging of the ASIC integrated MEMS device with exposed bond-pads system. A protective cover glass 1501 is used to protect the surface of fragile MEMS device and supporting shim 1502. The final packaging includes electrical components 1503 such as capacitors and a DC/DC converters attached to the packaging PCB 1505, and connectors 1504 are also fabricated for connecting CMOS ASIC integrated MEMS device. After completing the packaging, the device can be operated through the electrical connection of the packaging PCB.

FIG. 16 shows an example of 3D packaging model for CMOS ASIC integrated MEMS device showing clear aperture 1601 of the CMOS ASIC integrated MEMS device 1603 as well as protecting cover glass 1602.

The present invention of an ASIC (Application-Specific Integrated Circuit) integrated MEMS (Micro-Electro-Mechanical Systems) device with exposed wire bond-pads from bottom attached ASIC comprises a) a MEMS device with released moving structures on a substrate wherein the structures are used for the optical device to utilize the front surface of the MEMS device to reflect and control incident light, b) an ASIC circuitry chip wherein the ASIC circuitry chip comprising a plurality of electrode areas to provide electrical signal to the MEMS device, c) plurality of electrical connections through the substrate of the MEMS device wherein the electrical connections are connected to the ASIC circuitry chip and wherein the electrical connections comprise electrode area to receive electrical signals from the ASIC circuitry chip, and d) a plurality of exposed bond-pads from the ASIC circuitry chip wherein the bond-pads are exposed to outside wire bonding after split-dicing with the MEMS device and the ASIC circuitry chip.

The best merit of the method of building the ASIC integrated MEMS device with exposed wire bond-pads is ASIC wafer and MEMS wafer can be separately fabricated and wafer bonded after fabrication and before dicing. Thus productivity of building such devices can be higher than that by building individually processed device. The ASIC integrated MEMS device with exposed wire bond-pads are fabricated with wafer-level wafer bonding technologies (wafer to wafer bonding) and the ASIC integrated MEMS device with exposed wire bond-pads are diced to individual devices with the electrical connections through the MEMS wafer substrate between the MEMS device and ASIC chip.

Since fabricated separately, the MEMS wafer and ASIC wafer can be tested before wafer bonding, which can remove bad wafers before processing further and increase productivity. While main control signal and power comes through ASIC chip, the MEMS device can have separate bond-pads for testing and the MEMS device can have signal directly delivered to the device directly from the top of the MEMS device. These bond-pads can be connected separately for testing and controlling the MEMS device.

Basic main subjective matter of the present invention is that the ASIC chip has communication channels through the exposed wire bond-pads. When wafer bonding technique is applied to produce semiconductor device maybe through TSV technology, one of the wafer could not have external wire bonding accessibility since all of the areas are covered by another wafer. Thus to have exposed wire bond-pads can expand the usability of the semiconductor device. Especially for MEMS device, since the making process are so different (customized from the semiconductor process).

Thanks to the separate processes availability for MEMS wafer and ASIC wafer, the ASIC chip can use CMOS (Complementary Metal-Oxide Semiconductor) logic circuits to generate the electrical signals. There are lots of advantages for using CMOS logic for controlling electronics. Usability of CMOS logic was difficult to use for MEMS device especially when silicon MEMS process is used due to high processing temperature for silicon MEMS. In the present invention, separate wafer fabrication for MEMS and ASIC is used. Any fabrication method for ASIC build can be used independently from MEMS fabrication process. Thus advantages of CMOS logic can be introduced despite of using high temperature process for MEMS fabrication.

For fully control of the MEMS device, CMOS ASIC controller should have lots of sub circuitry such as column driver, row driver, and timing controller. CMOS logic can be operated using frame by frame control method which generates individual electrical control signals. CMOS logic can be used for maintaining the electrical control signal.

Since the ASIC can generate multiple electrical signals at the same time, MEMS device can have a plurality of degrees of freedom motion, wherein the plurality of degrees of freedom motion is controlled by the ASIC chip generated electrical signals. The subjective matter of the present invention is to provide a new technique for building such complicated devices and controlling. The control circuitry for the CMOS logic generates the plurality of the electrical signal and the generated signal are independently controlled to control the MEMS device. Thanks to the independent control, MEMS device can have a large number of degree of freedom motion. Especially for the micromirror array device, the large number of degrees of freedom motion is essential.

For building an ASIC (Application-Specific Integrated Circuit) integrated MEMS (Micro-Electro-Mechanical Systems) device with exposed wire bond-pads from bottom attached ASIC, many process steps are required such as a) making MEMS structures on a MEMS wafer just before the releasing etching step with a plurality of electrical connections through MEMS substrate, b) making a plurality of bottom electrode areas with metallization on the backside of the MEMS wafer for wafer bonding step, c) making plurality of top electrode area with metallization on the topside of the ASIC wafer for wafer bonding step, d) wafer-bonding the MEMS and the ASIC wafers with matching the bottom electrode areas of the MEMS wafer and the top electrode areas of the ASIC wafer, e) dicing the ASIC wafer with areas of ASIC chips without separation of the ASIC chips, f) releasing the MEMS structures by the etching process of the MEMS wafer, g) dicing the MEMS wafer with areas of MEMS devices, wherein the areas of the MEMS devices and the areas of the ASIC chips are partly overlapped with electrode areas (the top electrode areas of the ASIC chips and the bottom electrode areas of the MEMS devices) and partly not overlapped for exposed wire bond pads from the areas of the ASIC chips, and g) separating individual bonded devices from the bonded MEMS and ASIC wafers and exposing the electrical wire bond-pads on the ASIC chips.

Since the ASIC integrated MEMS device with exposed wire bond-pads is controlled through the exposed wire bond-pads, making exposed wire bond-pads is crucial. For the exposed wire bond-pads, split dicing method is proposed. And for using split dicing method, many steps of fabrication are required and sequenced.

Open while building MEMS wafer, controlling wafer stress is very important to avoid bending of the MEMS structures. To reduce stress of MEMS wafer, using thicker wafer is highly advantageous but the final product should also be thin enough. Especially for the present invention case, since wafer bonding technique is used, final device can be very thick. To avoid this thin wafer can be used with carrier wafer and later carrier wafer can be removed for thin final devices. While making the ASIC integrated MEMS device with exposed wire bond-pads, the steps of building can further comprise attaching carrier wafer to the MEMS wafer to reduce mechanical stress of the MEMS wafer, wherein the carrier wafer is removed after wafer-bonding the MEMS and the ASIC wafers.

Stealth dicing is relatively new technology which give lots of advantages, especially for the present invention. The present invention uses stealth dicing method by use of high energy laser pulses (eg. fs laser pulses). Since both the MEMS wafer and the ASIC wafer are diced separated and the wafer should have the position maintained for the processes, scribing like stealth dicing method is extremely helpful. The dicing step is done by stealth dicing wherein the stealth dicing is done by laser pulses and performs internal scribing of the ASIC wafer or the MEMS wafer.

Since the ASIC integrated MEMS device with exposed wire bond-pads has two wafers bonded, dicing direction is also very important. ASIC wafer is underneath, thus that the dicing of the ASIC wafer with areas of ASIC chips is performed from back side of the ASIC wafer is highly desirable. With same analogy, that the dicing the MEMS wafer with areas of MEMS devices is performed from front side of the MEMS wafer is desirable, wherein the front side of the MEMS wafer has the MEMS structures.

Thanks to the stealth dicing which is not exactly fully dicing rather scribing inside the wafer, dicing the MEMS wafer with areas of MEMS devices can be performed after the releasing the MEMS structures. Since MEMS structures are fragile after release process, usually release process is located at the last stage of the MEMS fabrication. But thanks to the stealth dicing, dicing can be performed after the release process. Also split dicing can be performed thanks to the stealth dicing advantages.

An ASIC (Application-Specific Integrated Circuit) integrated MEMS (Micro-Electro-Mechanical Systems) device with exposed wire bond-pads from bottom attached ASIC comprises a) a MEMS device with released moving structures on a substrate wherein the structures have a plurality of degree of freedom motions, b) an ASIC circuitry chip wherein the ASIC circuitry chip comprising a plurality of electrode areas to provide electrical signal to the MEMS device, c) a plurality of electrical connections through the substrate of the MEMS device wherein the electrical connections are connected between the ASIC circuitry chip and the MEMS device; and d) a plurality of exposed bond-pads from the ASIC circuitry chip wherein the bond-pads are exposed to outside wire bonding.

The ASIC and MEMS wafers are separately fabricated and wafer bonded after fabrication and before dicing and the ASIC integrated MEMS device with exposed wire bond-pads are fabricated with wafer-level wafer bonding technology (wafer to wafer bonding).

The MEMS device is controlled by the ASIC circuitry chip. The ASIC circuitry chip is controlled through the exposed bond-pads. The exposed bond-pads in the ASIC integrated MEMS device with exposed wire bond-pads are used for delivering control signal and power for the ASIC circuitry chip. At the same time, the MEMS device comprises bond-pads separately from the ASIC circuitry chip.

While the invention has been shown and described with reference to different embodiments thereof, it will be appreciated by those skills in the art that variations in form, detail, compositions and operation may be made without departing from the spirit and scope of the invention as defined by the accompanying claims.

What is claimed is:

1. An ASIC (Application-Specific Integrated Circuit) integrated MEMS (Micro-Electro-Mechanical Systems) device with exposed wire bond-pads from bottom attached ASIC comprising:
a. a MEMS device with released moving structures on a substrate wherein the structures are used for the optical device to utilize the front surface of the MEMS device to reflect and control incident light;
b. an ASIC circuitry chip wherein the ASIC circuitry chip comprising a plurality of electrode areas to provide electrical signal to the MEMS device;
c. a plurality of electrical connections through the substrate of the MEMS device wherein the electrical connections are connected to the ASIC circuitry chip and wherein the electrical connections comprise electrode area to receive electrical signals from the ASIC circuitry chip; and
d. a plurality of exposed bond-pads from the ASIC circuitry chip wherein the bond-pads are exposed to outside wire bonding after split-dicing with the MEMS device and the ASIC circuitry chip;
wherein said ASIC and MEMS wafers are separately fabricated and wafer bonded after fabrication and before dicing, and said ASIC integrated MEMS device with exposed wire bond-pads are fabricated with wafer-level wafer bonding technologies (wafer to wafer bonding) and wherein said ASIC integrated MEMS device with exposed wire bond-pads are diced to individual devices with the electrical connections through the MEMS wafer substrate between the MEMS device and ASIC chip.

2. The ASIC integrated MEMS device with exposed wire bond-pads in claim 1, wherein the MEMS wafer and ASIC wafer are separately fabricated and tested before wafer bonding.

3. The ASIC integrated MEMS device with exposed wire bond-pads in claim 1, wherein the MEMS device has separate bond-pads for testing and signal on top of the MEMS device.

4. The ASIC integrated MEMS device with exposed wire bond-pads in claim 3, wherein the bond-pads are connected separately for testing and controlling the MEMS device.

5. The ASIC integrated MEMS device with exposed wire bond-pads in claim 1, wherein the ASIC chip has communication channels through the exposed wire bond-pads.

6. The ASIC integrated MEMS device with exposed wire bond-pads in claim 1, wherein the ASIC chip uses CMOS (Complementary Metal-Oxide Semiconductor) logic circuits to generate the electrical signals.

7. The ASIC integrated MEMS device with exposed wire bond-pads in claim 6, wherein the ASIC chip has control circuitry for CMOS logic, wherein the control circuitry comprises column driver, row driver, and timing controller.

8. The ASIC integrated MEMS device with exposed wire bond-pads in claim 7, wherein the CMOS logic circuits maintains the electrical signal until the control circuitry generates next electrical signal.

9. The ASIC integrated MEMS device with exposed wire bond-pads in claim 7, wherein the MEMS device has a plurality of degrees of freedom motion, wherein the plurality of degrees of freedom motion is controlled by the ASIC chip generated electrical signals.

10. The ASIC integrated MEMS device with exposed wire bond-pads in claim 1, wherein the control circuitry for the CMOS logic generates the plurality of the electrical signal, wherein the plurality of the electrical signals are independently controlled to control the MEMS device.

11. A method for making an ASIC (Application-Specific Integrated Circuit) integrated MEMS (Micro-Electro-Mechanical Systems) device with exposed wire bond-pads from bottom attached ASIC comprising steps of:
a. making MEMS structures on a MEMS wafer just before the releasing etching step with a plurality of electrical connections through MEMS substrate;
b. making a plurality of bottom electrode areas with metallization on the backside of the MEMS wafer for wafer bonding step;
c. making plurality of top electrode area with metallization on the topside of the ASIC wafer for wafer bonding step;
d. wafer-bonding the MEMS and the ASIC wafers with matching the bottom electrode areas of the MEMS wafer and the top electrode areas of the ASIC wafer;
e. dicing the ASIC wafer with areas of ASIC chips without separation of the ASIC chips;
f. releasing the MEMS structures by the etching process of the MEMS wafer;
g. dicing the MEMS wafer with areas of MEMS devices, wherein the areas of the MEMS devices and the areas of the ASIC chips are partly overlapped with electrode areas (the top electrode areas of the ASIC chips and the bottom electrode areas of the MEMS devices) and partly not overlapped for exposed wire bond pads from the areas of the ASIC chips; and
h. separating individual bonded devices from the bonded MEMS and ASIC wafers and exposing the electrical wire bond-pads on the ASIC chips;
wherein the exposed electrical wire-bonds-pads are later connected to external circuit for operating the ASIC integrated MEMS device with exposed wire bond-pads.

12. The method for making an ASIC integrated MEMS device with exposed wire bond-pads in claim 11 further comprises attaching carrier wafer to the MEMS wafer to reduce mechanical stress of the MEMS wafer, wherein the carrier wafer is removed after wafer-bonding the MEMS and the ASIC wafers.

13. The method for making an ASIC integrated MEMS device with exposed wire bond-pads in claim 11, wherein the dicing step is done by stealth dicing wherein the stealth dicing is done by laser pulses and performs internal scribing of the ASIC wafer or the MEMS wafer.

14. The method for making an ASIC integrated MEMS device with exposed wire bond-pads in claim 11, wherein the dicing the ASIC wafer with areas of ASIC chips is performed from back side of the ASIC wafer.

15. The method for making an ASIC integrated MEMS device with exposed wire bond-pads in claim 11, wherein the dicing the MEMS wafer with areas of MEMS devices is performed from front side of the MEMS wafer, wherein the front side of the MEMS wafer has the MEMS structures.

16. The method for making an ASIC integrated MEMS device with exposed wire bond-pads in claim 11, wherein the dicing the MEMS wafer with areas of MEMS devices is performed after the releasing the MEMS structures.

17. An ASIC (Application-Specific Integrated Circuit) integrated MEMS (Micro-Electro-Mechanical Systems) device with exposed wire bond-pads from bottom attached ASIC comprising:
a. a MEMS device with released moving structures on a substrate wherein the structures have a plurality of degree of freedom motions;
b an ASIC circuitry chip wherein the ASIC circuitry chip comprising a plurality of electrode areas to provide electrical signal to the MEMS device;
C. a plurality of electrical connections through the substrate of the MEMS device wherein the electrical connections are connected between the ASIC circuitry chip and the MEMS device; and
d. a plurality of exposed bond-pads from the ASIC circuitry chip wherein the bond-pads are exposed to outside wire bonding;
wherein said ASIC and MEMS wafers are separately fabricated and wafer bonded after fabrication and before dicing and said ASIC integrated MEMS device with exposed wire bond-pads are fabricated with wafer-level wafer bonding technology (wafer to wafer bonding).

18. The ASIC integrated MEMS device with exposed wire bond-pads in claim 17, wherein the MEMS device is controlled by the ASIC circuitry chip.

19. The ASIC integrated MEMS device with exposed wire bond-pads in claim 17, wherein the ASIC circuitry chip is controlled through the exposed bond-pads.

20. The ASIC integrated MEMS device with exposed wire bond-pads in claim 17, wherein the exposed bond-pads are used for delivering control signal and power for the ASIC circuitry chip.
